(19) United States
(12) Patent Application Publication
(10) Pub. No.: US 2026/0074543 A1
(43) Pub. Date: Mar. 12, 2026

(54) SURFACE STATE OF CHARGE BASED TRACTION BATTERY POWER CAPABILITY

(71) Applicant: FORD GLOBAL TECHNOLOGIES, LLC, Dearborn, MI (US)

(72) Inventors: Xiaohong Nina DUAN, Canton, MI (US); Yonghua LI, Ann Arbor, MI (US); Donnell Matthew WASHINGTON, Northville, MI (US)

(21) Appl. No.: 18/826,516

(22) Filed: Sep. 6, 2024

(51) Int. Cl. H02J 7/00; G01R 31/388; H01M 50/569

(52) U.S. Cl. CPC H02J 7/82; G01R 31/388; H01M 50/569; H02J 7/94; H02J 7/96; H02J 7/977

(57) ABSTRACT

A traction battery is charged or discharged according to power limits that are based on generated state of charge values for the traction battery such that, for a 1C discharge rate of the traction battery at a temperature of 0° C., measured terminal voltage values of the traction battery continue to track terminal voltage values that are a function of the generated state of charge values as current throughput of the traction battery increases.

### TECHNICAL FIELD

The present disclosure relates to a method and system for estimating a power capability of a traction battery of a vehicle.

### BACKGROUND

Electric vehicles (EVs) rely on one or more traction batteries for providing power to an electric machine for propulsion. Operating characteristics of the traction batteries, such as the power capability, the terminal voltage, and the state-of-charge (SOC), may be monitored in controlling the operation of the traction batteries and/or the vehicles.

### SUMMARY

A vehicle includes a traction battery and one or more controllers that charge or discharge the traction battery according to power limits that are based on generated state of charge values for the traction battery such that, for a 1C discharge rate of the traction battery at a temperature of 0° C., measured terminal voltage values of the traction battery continue to track terminal voltage values that are a function of the generated state of charge values as current throughput of the traction battery increases.

A vehicle power system includes one or more controllers that discharge a traction battery according to output representing a power capability of the traction battery that is based on parameters indicative of a change in surface iron amount of one or more cells of the traction battery.

A method includes charging and discharging a traction battery of a vehicle according to power limits that are based on surface states of charge associated with the traction battery.

### BRIEF DESCRIPTION OF THE DRAWINGS

FIG. 1 illustrates an example block topology of an electrified vehicle illustrating drivetrain and energy storage components.

FIG. 2 illustrates a block diagram of an arrangement for a traction battery controller of a battery electric vehicle (BEV) to monitor a traction battery of the BEV.

FIG. 3 illustrates a schematic diagram of a conventional equivalent circuit model (ECM) of the traction battery.

FIG. 4 illustrates a flow diagram of a process for operating the vehicle.

FIG. 5 illustrates constant input simulation results at different temperatures from an open circuit voltage (OCV) model with local SOCs.

FIG. 6 illustrates different C rates of constant input simulation results from the OCV model with local SOCs.

FIG. 7 illustrates drive cycle simulation results at low temperatures from the OCV model with local SOCs.

FIG. 8 illustrates drive cycle simulation results at low temperatures and low SOC from the OCV model with local SOCs.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes a method and system for estimating a power capability of a traction battery of a vehicle. More specifically, the present disclosure proposes a method and system for estimating a power capability of a traction battery based on a surface SOC of battery electrodes.

In conventional battery voltage and power calculations, the (OCV) is commonly used. OCV represents the potential difference between the positive and negative electrode surfaces of a battery cell and is directly influenced by the cell's SOC. Typically, SOC is calculated by integrating the current over time, relative to the battery's capacity. The SOC-OCV relationship is derived under static conditions, where the battery is at rest with no current flow for an extended period, allowing equilibrium to be reached.

However, when a battery experiences current flow, whether constant or dynamic, the potential difference between the electrodes deviates from the OCV. This is because the SOC at the electrode surfaces changes with current flow, even though the overall SOC calculated through current integration remains the same.

A strategy is introduced for calculating cell voltage and power by directly using the potential difference between the positive and negative electrode surfaces. This potential difference is determined by the local SOC at the reaction surfaces. The local SOC is estimated by combining the average SOC (derived from current integration) with a delta SOC term. This delta SOC accounts for the effects of current flow history and temperature, capturing the dynamic changes in SOC at the reaction surfaces.

The difference between the local SOC and the average SOC is constrained by dynamic limits, which are influenced by factors such as current history, temperature, and the direction of current flow. These limits tend to zero when current flow ceases for a sufficient period, allowing the battery to reach a static state and enabling the local SOC to converge with the average SOC. When current flow resumes, the limits become non-zero, reflecting the dynamic behavior of the SOC at the reaction surfaces.

To ensure that the local SOC and average SOC difference remains within these dynamic limits, an anti-windup mechanism is applied. This method prevents the difference from exceeding the established limits. When the limits change, the delta SOC is adjusted accordingly, reflecting the evolving conditions within the battery.

The relationship between local SOC and the corresponding potential difference (DOP) is established using the SOC-OCV curve measured under static conditions. This curve serves as a reference for mapping the local SOC to the potential difference, even when dynamic current flow conditions are present.

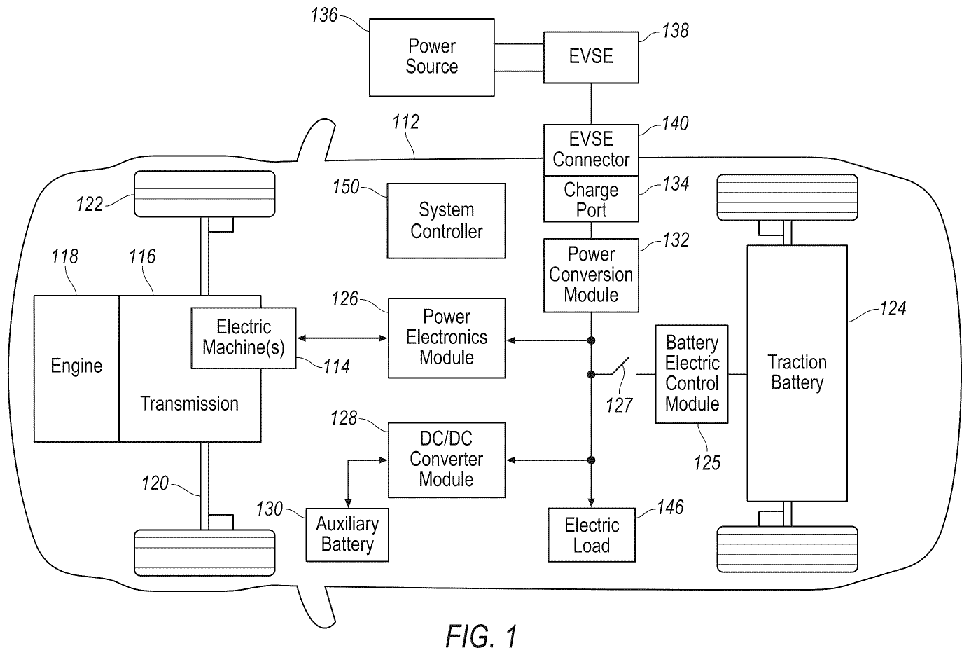

FIG. 1 illustrates a plug-in hybrid-electric vehicle (PHEV). A plug-in hybrid-electric vehicle 112 may comprise one or more electric machines (electric motors) 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to wheels 122. The electric machines 114 may provide propulsion and slowing capability when the engine 118 is turned on or off. The electric machines 114 may also function as generators and may provide fuel economy benefits by recovering energy that would be lost as heat in the friction braking system. The electric machines 114 may also reduce vehicle emissions by allowing the engine 118 to operate at more efficient speeds and allowing the hybrid-electric vehicle 112 to be operated in electric mode with the engine 118 off under certain conditions.

A traction battery or battery pack 124 stores energy that may be used by the electric machines 114. The vehicle battery pack 124 may provide a high voltage DC output. The traction battery 124 may be electrically coupled to one or more battery electric control modules (BECM) 125. The BECM 125 may be provided with one or more processors and software applications configured to monitor and control various operations of the traction battery 124. The traction battery 124 may be further electrically coupled to one or more power electronics modules 126. The power electronics module 126 may also be referred to as a power inverter. One or more contactors 127 may isolate the traction battery 124 and the BECM 125 from other components when opened and couple the traction battery 124 and the BECM 125 to other components when closed. The power electronics module 126 may also be electrically coupled to the electric machines 114 and provide the ability to bi-directionally transfer energy between the traction battery 124 and the electric machines 114. For example, a traction battery 124 may provide a DC voltage while the electric machines 114 may operate using three-phase AC current. The power electronics module 126 may convert the DC voltage to three-phase AC current for use by the electric machines 114. In a regenerative mode, the power electronics module 126 may convert three-phase AC current from the electric machines 114 acting as generators to DC voltage compatible with the traction battery 124. The description herein is equally applicable to a pure electric vehicle. For a pure electric vehicle, the hybrid transmission 116 may be a gear box connected to the electric machine 114 and the engine 118 may not be present.

In addition to providing energy for propulsion, the traction battery 124 may provide energy for other vehicle electrical systems. A vehicle may include a DC/DC converter module 128 that converts the high voltage DC output of the traction battery 124 to a low voltage DC supply that is compatible with other low-voltage vehicle loads. An output of the DC/DC converter module 128 may be electrically coupled to an auxiliary battery 130 (e.g., 12V battery).

The vehicle 112 may be a battery electric vehicle (BEV) or a plug-in hybrid electric vehicle (PHEV) in which the traction battery 124 may be recharged by an external power source 136. The external power source 136 may be a connection to an electrical outlet. The external power source 136 may be an electrical power distribution network or grid as provided by an electric utility company. The external power source 136 may be electrically coupled to electric vehicle supply equipment (EVSE) 138. The EVSE 138 may provide circuitry and controls to manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EVSE connector 140 may have pins that mate with corresponding recesses of the charge port 134. Alternatively, various components described as being electrically coupled may transfer power using a wireless inductive coupling. Although the vehicle 112 is illustrated as a BEV or PHEV with reference to FIG. 1, the present disclosure is not limited thereto. The vehicle 112 may also be a hybrid electric vehicle (HEV) or a fuel cell electric vehicle (FCEV) under essentially the same concept.

One or more electrical loads 146 may be coupled to the high-voltage bus. The electrical loads 146 may have an associated controller that operates and controls the electrical loads 146 when appropriate. Examples of electrical loads 146 may be a heating module, an air-conditioning module, or the like.

The various components discussed may have one or more associated controllers to control and monitor the operation of the components. The controllers may communicate via a serial bus (e.g., Controller Area Network (CAN)) or via discrete conductors. A system controller 150 may be present to coordinate the operation of the various components. It is noted that the system controller 150 is used as a general term and may include one or more controller devices configured to perform various operations in the present disclosure. For instance, the system controller 150 may be programmed to enable a powertrain control function to operate the powertrain of the vehicle 112. The system controller 150 may be further programmed to enable a telecommunication function with various entities (e.g., a server) via a wireless network (e.g., a cellular network).

The system controller 150 and/or the BECM 125, individually or combined, may be programmed to perform various operations regarding the traction battery 124. The traction battery 124 may be a rechargeable battery made of one or more rechargeable cells (e.g., lithium-ion cells). For instance, the BECM 125 may be a traction battery controller operable for managing the charging and discharging of the traction battery 124 and for monitoring operating characteristics of the traction battery 124. The BECM 125 may be operable to implement algorithms to measure (e.g., detect or estimate) the operating characteristics of the traction battery 124. The BECM 125 may control the operation and performance of the traction battery 124 based on the operating characteristics. The operation and performance of other systems and components of the vehicle 112 may be controlled based on the operating characteristics of the traction battery 124.

Operating characteristics of the traction battery 124 may include various parameters. For instance, the operating characteristics may include the charge capacity and the SOC of the traction battery 124. The charge capacity of the traction battery 124 is indicative of the maximum amount of electrical energy that the traction battery 124 may store.

Another operating characteristic of the traction battery 124 is the power capability of the traction battery 124. The power capability of the traction battery 124 is a measure of the maximum amount of power the traction battery 124 can provide (i.e., discharge) or receive (i.e., charge) for a specified time period. As such, the power capability of the traction battery 124 corresponds to discharge and charge power limits which define the amount of electrical power that may be supplied from or received by the traction battery 124 at a given time. These limits can be provided to other vehicle controls, for example, through the system controller 150, so that the information can be used by systems that may draw power from or provide power to the traction battery 124. Vehicle controls need to know how much power the traction battery 124 can provide (discharge) or receive (charge) in order to meet the driver's driving demand and HVAC (Heating, Ventilation and Air Conditioning) demand and to optimize the energy usage. As such, knowing the power capability of the traction battery 124 allows electrical loads and sources to be managed such that the power requested is within the allowed voltage and current limits that the traction battery 124 can manage.

The power capability of the traction battery 124 and/or each battery cell may vary depending on a variety of factors. For instance, the power capability may depend on a terminal voltage of the positive and negative terminals of the traction battery 124 (and/or each battery cell). Conventionally, the terminal voltage is determined using an open circuit voltage based on an average SOC of the traction battery 124. While the average SOC of the traction battery 124 may be relatively accurate in reflecting the OCV in static conditions where the traction battery 124 is not being charged or discharged, the conventional utilization of the average SOC may cause inaccuracies in a dynamic load condition when the traction battery 124 is being charged or discharged. This is because the iron amount is unevenly distributed across the reaction surface of the traction battery 124. For instance, when the traction battery 124 is being discharged, an outer surface of the positive electrode may be associated with a higher iron concentration compared to the inner portion of the positive electrode, whereas an outer surface of the negative electrode may be associated with a lower iron amount compared to the inner portion of the negative electrode. Since the battery cells are connected via only the outer surface of the electrodes, it is the characteristics associated with the outer surface that matter most and using the average SOC which reflects the average iron amount may cause inaccuracies. The present disclosure proposes a method and system to more accurately determine the power capability of the traction battery 124, and thus the power limits, using the battery SOC based on the surface iron amounts of the respective electrodes of battery cells.

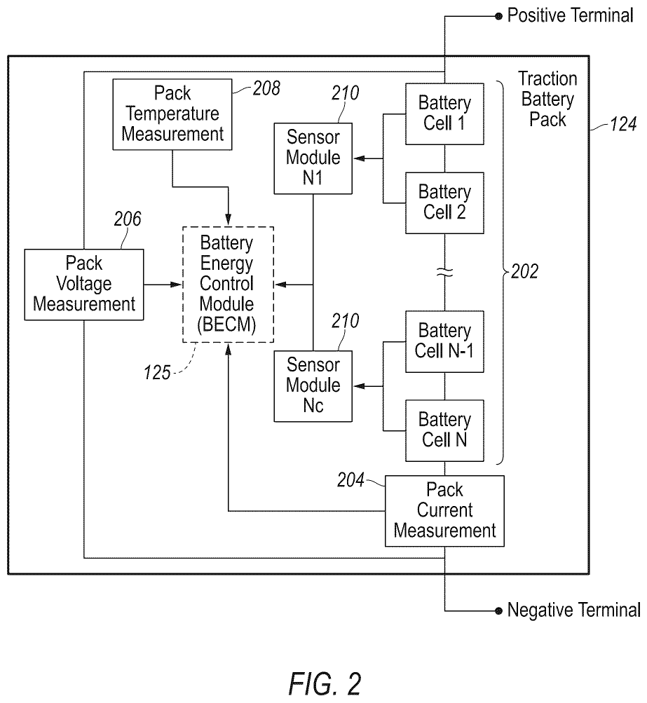

Referring to FIG. 2, with continuing reference to FIG. 1, a block diagram of an arrangement for the BECM 125 to monitor the traction battery 124 is illustrated. In the present example, the BECM 125 may be integrated with the traction battery 124 although the present disclosure is not limited thereto. The traction battery 124 includes a plurality of battery cells 202. The battery cells 202 may be physically connected together (e.g., connected in series as illustrated in FIG. 2).

The BECM 125 may be operable to monitor pack level characteristics of the traction battery 124 such as battery current 204, battery pack voltage 206, and battery temperature 208. The battery current 204 is the current output (i.e., discharged) from or input (i.e., charged) to the traction battery 124. The battery pack voltage 206 is the terminal voltage of the traction battery 124.

The BECM 125 may also be operable to measure and monitor battery cell level characteristics of battery cells 202 of the traction battery 124. For example, terminal voltage, current, and temperature of one or more of the battery cells 202 may be measured. The BECM 125 may use one or more battery sensors 210 to measure the battery cell level characteristics. The battery sensors 210 may measure the characteristics of one or multiple of the battery cells 202. The BECM 125 may utilize an Nc number of the battery sensors 210 to measure the characteristics of all the battery cells 202. Each of the battery sensors 210 may transfer the measurements to the BECM 125 for further processing and coordination. In one embodiment, the battery sensors 210 functionality may be incorporated internally to the BECM 125.

The traction battery 124 may have one or more temperature sensors such as thermistors in communication with the BECM 125 to provide data indicative of the temperature of the battery cells 202 of the traction battery 124. The vehicle 112 may further include one or more temperature sensors 208 to provide data indicative of ambient temperature for the BECM 125 to monitor the ambient temperature.

The BECM 125 may control the operation and performance of the traction battery 124 based on the monitored traction battery and battery cell level characteristics. For instance, the BECM 125 may use the monitored characteristics to measure (e.g., detect or estimate) operating characteristics of the traction battery 124 (e.g., the power capability, the SOC, the internal resistance and the like) such as for use in controlling the traction battery 124 and/or vehicle 112.

As known by those of ordinary skill in the art, the BECM 125 may estimate values of parameters of an equivalent circuit model (ECM) (e.g., resistances and capacitances of circuit elements of the ECM) and values of states of the ECM (e.g., voltages and currents across circuit elements of the ECM) through recursive estimation based on such measurements. For instance, the BECM 125 may use some adaptive estimation method, such as an extended Kalman filter (EKF), to estimate the values of the model parameters and model states.

For the values of the operating characteristics of the traction battery 124 measured by the BECM 125 to be accurate with the actual values of the operating characteristics of the traction battery, the ECM must accurately model the traction battery 124. For the ECM to accurately model the traction battery 124, (i) the ECM should have an adequate set of parameters (e.g., resistances and capacitances of circuit elements of the ECM) and (ii) the estimated values of the model parameters and model states should be at least substantially similar to the values of the parameters and the states of an ECM that accurately models the traction battery 124 (i.e., the estimated parameter and state values have to be at least substantially similar to the actual parameter and state values).

As set forth, an accurate model of the traction battery 124 enables the BECM 125 to properly control the traction battery 124 which directly affects vehicle performance and driving range for a given full charge. ECMs are widely used in electrified vehicle traction battery control systems to satisfy real time control system requirements for calculation of speed and RAM/ROM usage. Particularly, an n-RC ECM where n=1 or 2 is widely used (an n-RC ECM is a type of ECM having “n” RC circuit elements each including a resistor (“R”) parameter and a capacitor (“C”) parameter; with n=1, a 1-RC ECM includes one such RC circuit element; and with n=2, a 2-RC ECM includes two such RC circuit elements). As indicated, the parameters for the ECM are learned with an online learning method such as Kalman Filter or extended Kalman filter (EKF).

In accordance with the present disclosure, the BECM 125 employs an equivalent circuit model of the traction battery 124 that efficiently represents complex battery dynamics of the traction battery 124. The number of parameters of the proposed ECM are less than the number of parameters of multi-RC pair ECMs having three or more RC circuit elements, and the parameters of the proposed ECM can be learned using EKF or similar methods under reasonable BECM capabilities such as CPU utilization ratio and RAM/ROM availability.

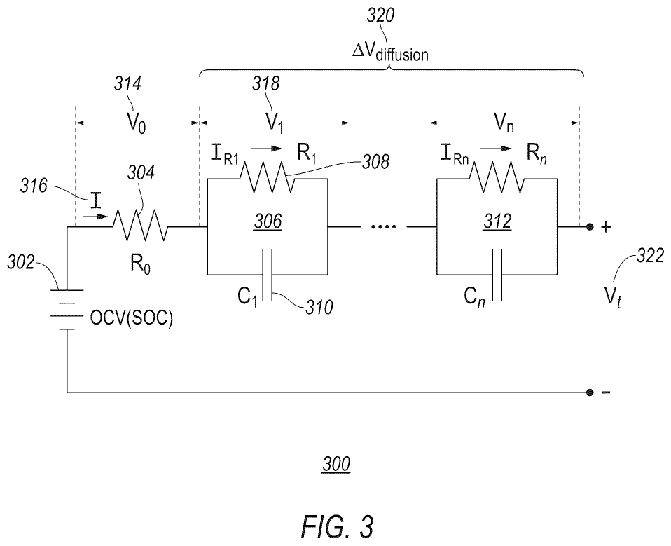

Referring to FIG. 3, with continuing reference to FIGS. 1 and 2, a schematic diagram of an ECM 300 of the traction battery 124 is shown. Per the ECM 300, the traction battery 124 is modeled as a circuit having in series a voltage source (OCV/(SOC)) 302, a resistor R0 304, a first RC pair 306 having a first resistor R1 308 and a first capacitor C1 310 connected in parallel, and one or more such additional RC pairs 312. As such, the conventional ECM 300 is an n-RC ECM where n≥2.

The voltage source 302 represents the open-circuit voltage (OCV) of the traction battery 124. The OCV of the traction battery 124 depends on the SOC and the temperature of the traction battery 124. The resistor R0 304 represents an internal resistance of the traction battery 124. The RC pairs represent the diffusion process of the traction battery 124. As such, the diffusion process of the traction battery 124 in the conventional ECM 300 may be described with RC pairs R1 and C1, . . . , Rn and Cn.

Voltage V0 314 is the voltage drop across the resistor R0 304 due to battery current I 316 which flows across the resistor R0 304. Voltage V1 318 is the voltage drop across the first RC pair 306 due to battery current IRI which flows across the resistor R1 308. A voltage drop is across each additional RC pair 312. The total voltage across all RC pairs may be represented as a diffusion voltage ΔVdiffusion 320. Voltage Vt 322 is the voltage across the terminals of the traction battery 124 (i.e., the terminal voltage). The terminal voltage Vt 322 may be determined using the following equation in a conventional approach:

$${V}_{t} = OCV ( {SOC}_{a v e} ) - {IR}_{0} - Δ {V}_{diffusion} \qquad ( 1 )$$

wherein the OCV of the voltage source 302 may vary and be determined as a function of an average SOC of the traction battery 124 (and/or one or more battery cells 202).

As discussed above, while the average SOC of the traction battery 124 may be relatively accurate in reflecting OCV in static conditions when the traction battery 124 is fully rested, the utilization of the average SOC to determine the terminal voltage V1 322 may cause inaccuracies in dynamic load conditions when the traction battery 124 is being charged or discharged or shortly after the charge/discharge without being fully rested. The iron amount may be unevenly distributed across the electrodes of the battery cells 202 in those conditions. The present disclosure proposes a method for more accurately determining the terminal voltage V1 322 using a difference in potential (DOP) between the positive and negative electrodes based on the SOC on the reaction surface of the respective electrodes as presented in the following equation:

$${V}_{t} = DOP ( {SOC}_{surface} ) - {IR}_{0} - Δ {V}_{diffusion} \qquad ( 2 )$$

wherein SOC_{surface} denotes the local SOC at the reaction surface (surface SOC) of the respective battery cells 202.

In the present disclosure, the surface SOC may be derived from the average SOC of the respective battery cell 202. There are a number of methods to determine the average SOC of the battery cell. For instance, the average SOC may be determined using the equation below:

$${SOC}_{a v e} = {SOC}_{i n i} - {\int }_{0}^{t} \frac{100 * I ( t )}{{Q}_{\frac{b a t t}{c e l l}}} dt ( \% ) \qquad ( 3 )$$

wherein the Q_{batt/cell} denotes the capacity of the corresponding traction battery 124 or battery cell 202, SOCᵢₙᵢ denotes the initial battery/cell SOC at the beginning of a time frame, and t denotes the time elapse since the beginning of the time frame.

The difference between the surface SOC and the average SOC of the battery cell 202 may be represented as a ΔSOC influenced by various factors such as the cell temperature, the recent current history, the cell's average SOC or the like. Thus, the surface SOC may be represented as:

$${SOC}_{surface} = {SOC}_{ave} + Δ SOC \qquad ( 4 )$$

For instance, when the battery cell is being discharged, an increase in average discharge current or weighted average discharge current in most recent history leads to the ΔSOC trending more negatively with the increase of accumulated current increase until it reaches predefined limits. Conversely, a decrease in the average discharge current or weighted average discharge current in most recent history leads to the amplitude of the ΔSOC to diminish towards zero. The rate of change in the ΔSOC's growth and reduction may vary based on factors such as the cell temperature and the current history in the most recent time frame. Likewise, when the battery cell is being charged, an increase in accumulated charge current causes the amplitude of the ΔSOC to shift towards a positive direction until reaching limits, while a decrease in accumulated charge current in the charging direction leads to the amplitude of the ΔSOC shrinking towards zero. The rate of change in the ΔSOC growth and reduction may also vary based on factors such as the cell temperature and the current in the most recent time history.

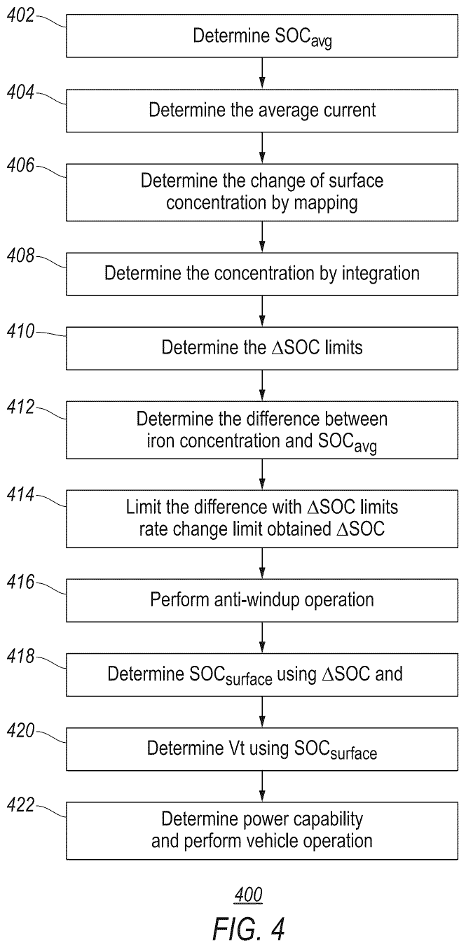

Referring to FIG. 4, an example flow diagram of a process 400 for operating the vehicle of one embodiment of the present disclosure is illustrated. With continuing reference to FIGS. 1 to 3, the operations of the process 400 may be individually or collectively implemented via the BECM 125 in combination with various components of the vehicle 112. For simplicity, the following description will be made with reference to the BECM 125. Further, it is noted that the operations of the process 400 may be applied to one or more individual cells and/or the entire traction battery 124 under essentially the same principle. The following description will be made with reference to a single one of the battery cells 202 for simplicity. At operation 402, the BECM 125 determines the average SOC of the battery cell 202 e.g., using equation (3) presented above. The average SOC determined at operation 402 may be used as a base value to determine the surface SOC subsequently.

At operation 404, the BECM 125 determines the average current (or weighted average current) lave. The average current lave may be calculated with a fix length time window TW2 before the present time t. Thus, the slide window is between (TW2, t). In the case that the weighted average is used current, the most recent current is weighted more than early ones during average calculation. Thus, weighting factors may be applied in a manner that assigns more weight to currents closer to the present time and gradually reduces the weight of currents further from the present time. These weighting factors may vary for different current directions and be determined based on whether the absolute difference is increasing or decreasing and the direction of current flow.

At operation 406, the BECM 125 determines the change of surface iron amount by mapping. For instance, the input current, I may be mapped into the change of surface iron amount jSC via temperature T and the average current lave. The mapping may be done through cell capacity Q and 2D table of temperature and average current lave, or through function j_{sc}=f(T, Iₐᵥₑ, Q).

At operation 408, The BECM 125 determines the iron amount by integration. The surface amount Csurface may be determined via integrating the change of surface iron amount using the following equations:

$$Δ {C}_{surface} ( t ) = {\int }_{{t}_{0}}^{t} {j}_{SC} dt \qquad ( 5 )$$

$${C}_{surface} ( t ) = {C}_{{surface}_{initial}} + Δ {C}_{surface} ( t ) \qquad ( 6 )$$

wherein, t₀ is the previous time of surface SOC_{surface} and the average SOCₐᵥₑ are equal, and C_{surface_initial} is the surface at to SOC_{surface} (t₀).

At operation 410, the BECM 125 determines the ΔSOC limits based on the temperature T and average current Iₐᵥₑ previously determined. The absolute value of limits for charge and discharge events may be different. In the present case, it is assumed that the charge limit is positive and discharge limit is negative. The ΔSOC limits for charge and discharge events are presented below:

$$Δ {SOC}_{{limit}_{charge}} = {f}_{ch} ( T , {I}_{ave} ) \qquad ( 7 )$$

$$Δ {SOC}_{{limit}_{discharge}} = {f}_{dis} ( T , {I}_{ave} ) \qquad ( 8 )$$

At operation 412, the BECM 125 determines the difference ΔSOC_{unL} between iron amount and average SOCₐᵥₑ using the following equation:

$$Δ {SOC}_{unL} ( t ) = {C}_{surface} ( t ) - {SOC}_{ave} ( t ) \qquad ( 9 )$$

At operation 414, the BECM 125 limits the difference with ΔSOC limits and rate change limit obtained ΔSOC.

There may be two limits. The first limit is ΔSOC bound limits. If the value of difference ΔSOC_{unL} is within the limits, the ΔSOC bound limits may output the same value of ΔSOC_{unL}. Otherwise, the ΔSOC may be trimmed into the value of ΔSOC_{limit_charge} or ΔSOC_{limit_discharge} according to whether the difference ΔSOC_{unL} is greater or less than zero. In the depletion case, for instance, the difference ΔSOC_{unL} is negative. In the charging case, the difference ΔSOC_{unL} is positive.

The second limit is a rate change limit, which limits the rate of change for

$$\frac{Δ SOC ( t ) - Δ SOC ( t - dt )}{dt}$$

within predefined range. The rate limit may be different for positive or negative ΔSOC.

At operation 416, the BECM 125 performs anti-windup operations. If the ΔSOC_{unL} is out of the limits of ΔSOC, the anti-windup operation will be performed. In the present example, the anti-windup operation will reduce the value of C_{surface}(t) for ΔSOC_{unL}>0, and increase the value of C_{surface}(t) for ΔSOC_{unL}<0.

At operation 418, the BECM 125 determines the surface SOC by adjusting the average SOC using the ΔSOC.

With the surface SOC of the battery cell 202 determined, at operation 420, the BECM 125 determines the terminal voltage Vt 322 of the battery cell 202 by applying the surface SOC to equation (2) presented above.

At operation 422, the BECM 125 estimates the power capability of the traction battery 124 using the one or more terminal voltage Vt 322 of the battery cell 202 and performs vehicle operations using the power capability.

The operations of the process 400 may be applied to various situations. With continuing reference to the nRC ECM 300 illustrated with reference to FIG. 3, the states of the ECM 300 may be represented below:

$$[ \text{} \begin{matrix}\frac{{dOSC}_{ave} ( t )}{dt} \\ \frac{{dV}_{1} ( t )}{dt} \\ \frac{{dV}_{2} ( t )}{dt} \\ ⋮ \\ \frac{{dV}_{n} ( t )}{dt} \\ \frac{{dR}_{0} ( t )}{dt} \\ \frac{{dR}_{1} ( t )}{dt} \\ \frac{d {τ}_{1} ( t )}{dt}\end{matrix} ] = [ \text{} \begin{matrix}0 & 0 & 0 & 0 & 0 & 0 & 0 & 0 & 0 \\ 0 & - \frac{1}{{τ}_{1}} & 0 & 0 & 0 & 0 & 0 & 0 & 0 \\ 0 & 0 & - \frac{1}{{τ}_{2}} & 0 & 0 & 0 & 0 & 0 & 0 \\ 0 & 0 & 0 & ⋮ & 0 & 0 & 0 & 0 & 0 \\ 0 & 0 & 0 & 0 & - \frac{1}{{τ}_{n}} & 0 & 0 & 0 & 0 \\ 0 & 0 & 0 & 0 & 0 & 0 & 0 & 0 & 0 \\ 0 & 0 & 0 & 0 & 0 & 0 & 0 & 0 & 0 \\ 0 & 0 & 0 & 0 & 0 & 0 & 0 & 0 & 0\end{matrix} ] [ \text{} \begin{matrix}{SOC}_{ave} \\ {V}_{1} \\ {V}_{2} \\ ⋮ \\ {V}_{n} \\ {R}_{0} \\ {R}_{1} \\ {τ}_{1}\end{matrix} ] + [ \text{} \begin{matrix}- \frac{1}{Q} \\ \frac{{R}_{1}}{{τ}_{1}} \\ \frac{{R}_{2}}{{τ}_{2}} \\ ⋮ \\ \frac{{R}_{n}}{{τ}_{n}} \\ 0 \\ 0 \\ 0\end{matrix} ] * I ( t ) + w ( t ) \qquad ( 5 )$$

wherein τₙ represents a time constant indicative of a response time of each respective RC pair, and w denotes process noise. The depth of potential DOP may be determined as:

$$DOP ( t ) = OCV ( {SOC}_{surface} ( t ) ) \qquad ( 6 )$$

wherein SOC_{surface}(t) is determined based on the cell load history at time t using equation (4) presented above.

The voltage of each RC pair Vᵢ (tₖ) may be determined as a function of the resistance R and time constant τ using the equation below:

$${V}_{i} ( {t}_{k} ) = I ( {t}_{k} ) {R}_{i} ( 1 - {e}^{- \frac{d t}{{τ}_{i}}} ) + {V}_{i} ( {t}_{k - 1} ) \qquad ( 7 )$$

Therefore, the terminal voltage Vₜ 322 may be determined as:

$$V ( t ) = DOP ( t ) - {R}_{0} * I ( t ) - {V}_{1} ( t ) - {V}_{2} ( t ) - {V}_{3} ( t ) - … {V}_{n} ( t ) + μ ( t ) \qquad ( 8 )$$

wherein μ(t) denotes observation noise.

With the terminal voltage Vₜ 322 determined, the current limits of the traction battery and/or the battery cell 202 may be calculated. In the discharge stage, the discharge current limit may be determined as:

$${i}_{max} = \frac{ocv ( {SOC}_{local} ) - {V}_{t min} - {V}_{1} ( 0 ) {e}^{- \frac{t}{{τ}_{1}}} - {V}_{2} ( 0 ) {e}^{- \frac{t}{{τ}_{2}}} - {V}_{3} ( 0 ) {e}^{- \frac{t}{{τ}_{3}}} ... - {V}_{n} ( 0 ) {e}^{- \frac{t}{{τ}_{n}}}}{{R}_{0} + {R}_{1} ( 1 - {e}^{- \frac{t}{{τ}_{1}}} ) + {R}_{2} ( 1 - {e}^{- \frac{t}{{τ}_{2}}} ) + … {R}_{n} ( 1 - {e}^{- \frac{t}{{τ}_{n}}} )} \qquad ( 9 )$$

wherein Vₜₘᵢₙ denotes the battery minimum voltage limit. The voltage under the maximum discharge current may be determined using the following equation:

$${V}_{t} dis = ocv ( \text{} {SOC}_{surface} ( \text{} t ) ) - [ {V}_{1} ( 0 ) {e}^{- \frac{t}{{τ}_{1}}} + {V}_{2} ( 0 ) {e}^{- \frac{t}{{τ}_{2}}} + {V}_{3} ( 0 ) {e}^{- \frac{t}{{τ}_{3}}} … + {V}_{n} ( 0 ) {e}^{- \frac{t}{{τ}_{n}}} ] - {i}_{max} [ {R}_{1} ( 1 - {e}^{- \frac{t}{{τ}_{1}}} ) + {R}_{2} ( 1 - {e}^{- \frac{t}{{τ}_{2}}} ) + … {R}_{n} ( 1 - {e}^{- \frac{t}{{τ}_{n}}} ) ] \qquad ( 10 )$$

The discharge power capability of the traction battery 124 and/or the battery cell 202 may be determined as:

$${P}_{{cap}_{dis}} ( t ) = \{ \begin{matrix}{i}_{max * {v}_{min}} & if {i}_{max < {i}_{dis} , limit} \\ {i}_{dis} , limit * {V}_{t} dis & Otherwise\end{matrix} \qquad ( 11 )$$

With the discharge power capability determined, the system controller 150 and/or the BECM 125 may operate the discharge of the traction battery 124 using the power capability. For instance, responsive to detecting a power demand for propulsion from the electric machine 114 greater than the power capability of the traction battery 124, the system controller 150 and/or the BECM 125 may limit the power output from the traction battery 124 using the power capability.

In the charge stage, the maximum charge current may be defined as the minimum current since the current is negative. The maximum charge current may be determined as:

$${i}_{min} = \frac{ocv ( {SOC}_{surface} ) - {V}_{tmax} - {V}_{1} ( 0 ) {e}^{- \frac{t}{{τ}_{1}}} - {V}_{2} ( 0 ) {e}^{- \frac{t}{{τ}_{2}}} - {V}_{3} ( 0 ) {e}^{- \frac{t}{{τ}_{3}}} ... - {V}_{n} ( 0 ) {e}^{- \frac{t}{{τ}_{n}}}}{{R}_{0} + {R}_{1} ( 1 - {e}^{- \frac{t}{{τ}_{1}}} ) + {R}_{2} ( 1 - {e}^{- \frac{t}{{τ}_{2}}} ) + … {R}_{n} ( 1 - {e}^{- \frac{t}{{τ}_{n}}} )} \qquad ( 12 )$$

wherein Vₜₘₐₓ denotes the battery maximum voltage limit. The voltage under the maximum charge current may be determined using the following equation:

$${V}_{t} ch = ocv ( \text{} {SOC}_{surface} ( \text{} t ) ) - [ {V}_{1} ( 0 ) {e}^{- \frac{t}{{τ}_{1}}} + {V}_{2} ( 0 ) {e}^{- \frac{t}{{τ}_{2}}} + {V}_{3} ( 0 ) {e}^{- \frac{t}{{τ}_{3}}} … + {V}_{n} ( 0 ) {e}^{- \frac{t}{{τ}_{n}}} ] - {i}_{min} [ {R}_{1} ( 1 - {e}^{- \frac{t}{{τ}_{1}}} ) + {R}_{2} ( 1 - {e}^{- \frac{t}{{τ}_{2}}} ) + … {R}_{n} ( 1 - {e}^{- \frac{t}{{τ}_{n}}} ) ] \qquad ( 13 )$$

The charge power capability of the traction battery 124 and/or the battery cell 202 may be determined as:

$${P}_{{cap}_{ch}} ( t ) = \{ \begin{matrix}abs ( {i}_{max )} * {V}_{max} & if abs ( {i}_{min )} < {i}_{ch} , limit \\ {i}_{ch} , limit * {V}_{t} ch & Otherwise\end{matrix} \qquad ( 14 )$$

With the charge power capability determined, the system controller 150 and/or the BECM 125 may control the charge of the traction battery 124 using the power capability. For instance, the BECM 125 may limit the charge power of the traction battery 124 using the charge power capability.

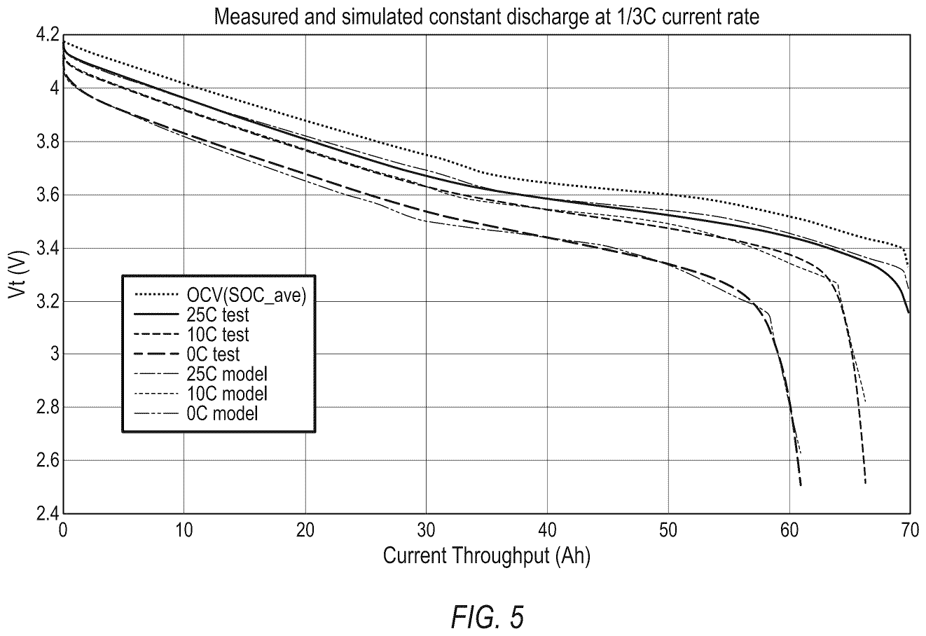

Referring to FIG. 5, simulations were conducted using the proposed model to evaluate the discharge current at a 1/3C rate constant across different temperatures. The results of the proposed model demonstrate that the predicted battery voltage is accurate.

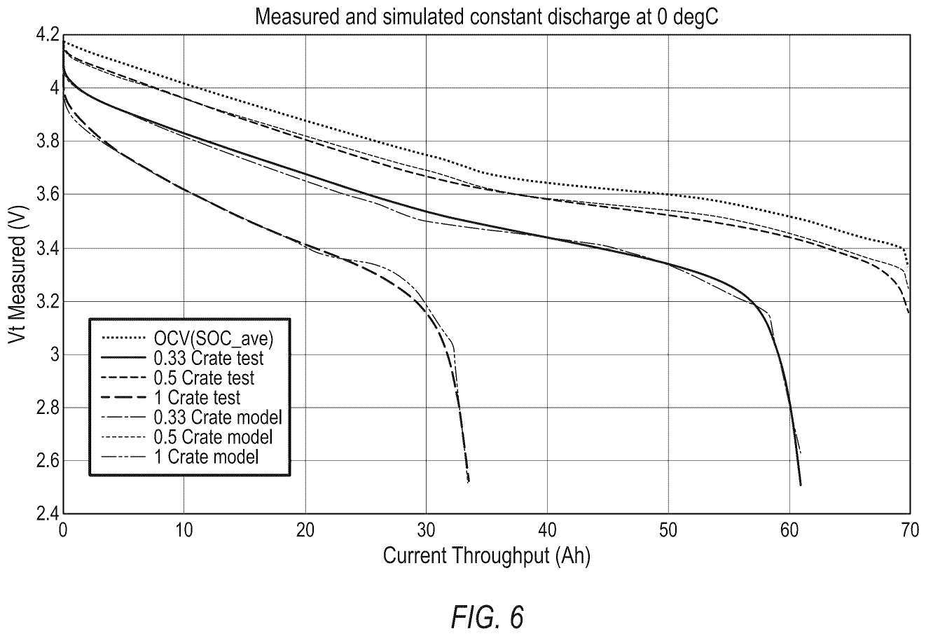

Referring to FIG. 6, simulations were performed using the proposed model for different discharge rates, including 1/3C, 1/2C, and 1C, all at a constant temperature of 0° C. The results indicate that the predicted battery voltage by the proposed method is accurate.

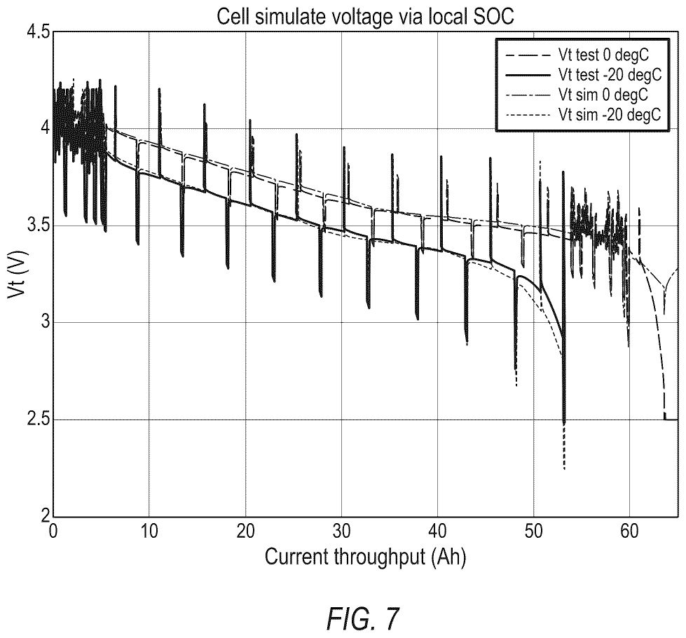

Referring to FIG. 7, the proposed model was used to simulate dynamic drive cycle currents. The results show that the predicted battery voltages are accurate.

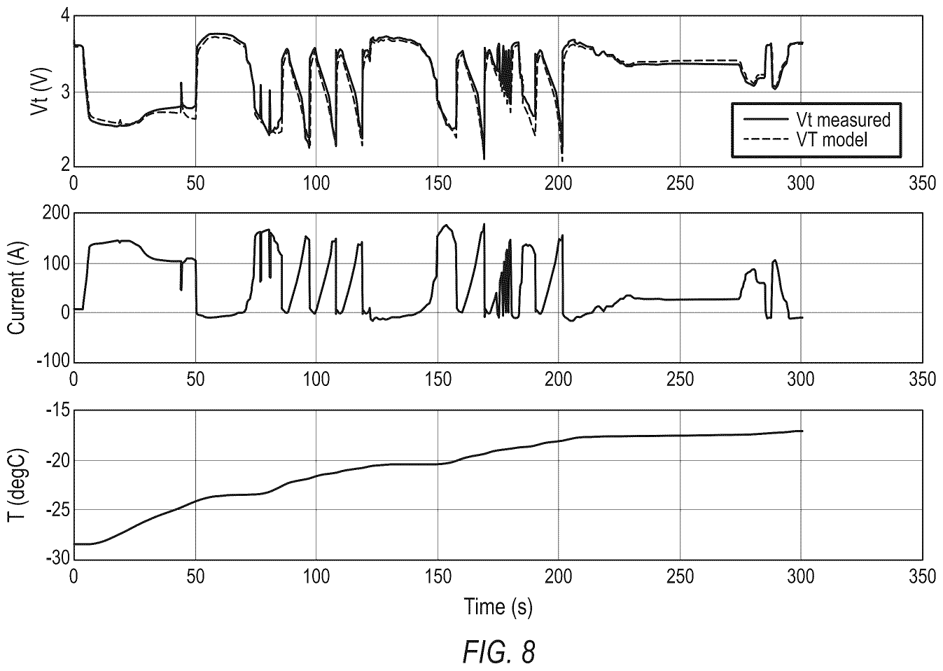

Referring to FIG. 8, simulations were conducted using the proposed model for another cold temperature drive profile. The input current and temperature conditions are shown. The simulation results indicate that the proposed model closely matches the measured terminal voltage.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle comprising:
a traction battery; and
one or more controllers programmed to charge or discharge the traction battery according to power limits that are based on generated state of charge values for the traction battery such that, for a 1C discharge rate of the traction battery at a temperature of 0° C., measured terminal voltage values of the traction battery continue to track terminal voltage values that are a function of the generated state of charge values as current throughput of the traction battery increases.

2. The vehicle of claim 1, wherein the measured terminal voltage values of the traction battery continue to track the terminal voltage values that are a function of the generated state of charge values as current throughput of the traction battery increases.

3. The vehicle of claim 1, wherein the generated state of charge values reflect a change in surface iron amount of one or more cells of the traction battery.

4. The vehicle of claim 1, wherein the one or more controllers are further programmed to produce the generated state of charge values based on an average state of charge value.

5. The vehicle of claim 4, wherein the one or more controllers are further programmed to produce the generated state of charge values based on a parameter that is influenced by cell temperature associated with the traction battery.

6. The vehicle of claim 4, wherein the one or more controllers are further programmed to produce the average state of charge value based on a capacity associated with the traction battery.

7. The vehicle of claim 1, wherein the function is defined by an equivalent circuit model of the traction battery.

8. A vehicle power system comprising:
one or more controllers programmed to discharge a traction battery according to output representing a power capability of the traction battery that is based on parameters indicative of a change in surface iron amount of one or more cells of the traction battery.

9. The vehicle power system of claim 8, wherein the parameters include generated state of charge values for the traction battery such that, for a 1C discharge rate of the traction battery at a temperature of 0° C., measured terminal voltage values of the traction battery continue to track terminal voltage values that are a function of the generated state of charge values as current throughput of the traction battery increases.

10. The vehicle power system of claim 9, wherein the measured terminal voltage values of the traction battery continue to track the terminal voltage values that are a function of the generated state of charge values as current throughput of the traction battery increases.

11. The vehicle power system of claim 8, wherein the output representing the power capability is further based on parameters indicative of an average state of charge of the traction battery.

12. The vehicle power system of claim 11, wherein the average state of charge of the traction battery is based on parameters indicative of a capacity associated with the traction battery.

13. A method comprising:
charging and discharging a traction battery of a vehicle according to power limits that are based on surface states of charge associated with the traction battery.

14. The method of claim 13, wherein the surface states of charge are such that measured terminal voltage values of the traction battery continue to track terminal voltage values that are a function of the surface states of charge as current throughput of the traction battery increases.

15. The method of claim 13, wherein the surface states of charge reflect a change in surface iron amount of one or more cells of the traction battery.

16. The method of claim 13, wherein the surface states of charge are based on an average state of charge.

17. The method of claim 13, wherein the surface states of charge are based on a parameter that is influenced by cell temperature associated with the traction battery.
